(19) United States
(12) Patent Application Publication
(10) Pub. No.: US 2013/0102117 A1
(43) Pub. Date: Apr. 25, 2013

(54) Manufacturing Processes for Field Effect Transistors Having Strain-Induced Chanels

(71) Applicant: Kai-Shiung Hsu, Hsin Chu (TW)

(72) Inventor: Kai-Shiung Hsu, Hsin Chu (TW)

(73) Assignee: Taiwan Semiconductor Manufacturing Co. Ltd., Hsin-Chu (TW)

(21) Appl. No.: 13/278,285

(22) Filed: Oct. 21, 2011

(51) Int. Cl. H01L 21/8238

(52) U.S. Cl. 438/218; 438/199; 257/E21.642; 257/E21.632

(57) ABSTRACT

One embodiment relates to a method of semiconductor manufacture. In this method, a strain inducing layer is formed over a p-type field effect transistor structure and an n-type field effect transistor structure. The strain inducing layer is removed from over the p-type field effect transistor while the strain inducing layer over the n-type field effect transistor is left in place. A treatment of the strain inducing layer over the n-type field effect transistor is performed after the strain-inducing layer has been removed from over the p-type field effect transistor.

### BACKGROUND

There is a continuing need to further scale semiconductor devices and improve semiconductor device performance. One characteristic that limits scalability and device performance is electron and hole mobility (which may also be referred to as “carrier mobility” or “channel mobility”) throughout the channel region of field effect transistors. As devices continue to shrink in size, the transistor channel regions also shrink in size. This can limit channel mobility.

One technique that may improve downward scaling limits and device performance is introduction of strain into the channel region, which can improve electron and hole mobility. Different types of strain, including expansive strain, uni-axial tensile strain, and compressive strain, have been introduced into channel regions in order to determine their effect on electron and/or hole mobility. For instance, compressive induced strain may be used to increase hole mobility in a PMOS type device, whereas tensile induced strain may be employed to increase electron mobility in an NMOS type device.

The present disclosure relates to improved manufacturing methods for field effect transistors having strain-induced channel regions.

### SUMMARY

The following presents a simplified summary in order to provide a basic understanding of one or more aspects of the invention. This summary is not an extensive overview of the invention. It is intended neither to identify key or critical elements of the invention nor to delineate the scope thereof. Rather, the primary purpose of the summary is to present some concepts of the invention in a simplified form as a prelude to the more detailed description that is presented later.

One embodiment relates to a method of semiconductor manufacture. In this method, a strain inducing layer is formed over p-type and n-type field effect transistor structures to impart tensile stress to a channel region of the n-type field effect transistor structure. The strain inducing layer is later removed from over the p-type field effect transistor, but remains in place over the n-type field effect transistor. A treatment of the strain inducing layer remaining over the n-type field effect transistor is then performed. This treatment imparts additional strain to the channel region of the n-type field effect transistor.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a flow diagram illustrating an exemplary method of fabricating a semiconductor device in accordance with some embodiments.

FIGS. 2-6 are cross-sectional views that collectively illustrate a semiconductor process flow making use of a treatment step that is ordered to impart additional strain to a channel region while limiting mouse bite defects in accordance with some embodiments.

### DETAILED DESCRIPTION

The present invention will now be described with reference to the attached drawings, wherein like reference numerals are used to refer to like elements throughout. The invention relates to methods and structures for influencing strain in an electrical region of a semiconductor device, by which one or more operational performance characteristics of the device may be improved. In the illustrated examples which follow, several implementations of the invention are shown and described which operate to improve carrier mobility in MOSFET type transistors.

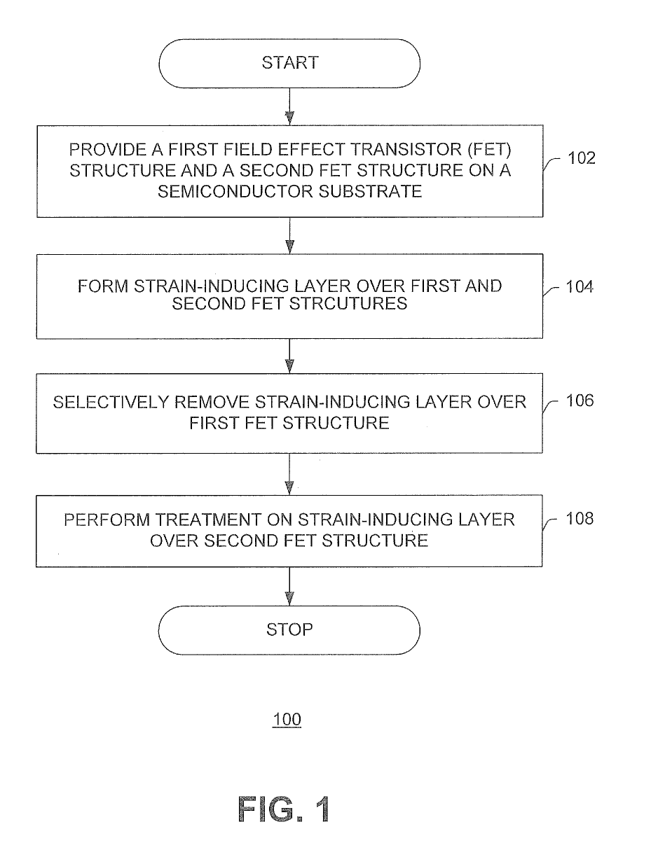

FIG. 1 shows a flow diagram of a manufacturing method 100 that employs a treatment for field effect transistors having strained channel regions in accordance with some embodiments. The method 100 starts at 102 when a first (e.g., p-type) field effect transistor structure and a second (e.g., n-type) field effect transistor structure are provided on a semiconductor substrate. At 104, a strain inducing layer is formed over the first and second field effect transistor structures. At 106, the strain inducing layer is selectively removed over the first (e.g., p-type) field effect transistor structure while being left in place over the second (e.g., n-type) field effect transistor structure. At 108, a treatment is applied to the remaining strain inducing layer to break bonds in the remaining strain inducing layer. This treatment can be implemented as a UV cure, thermal process step (e.g., anneal), plasma treatment, or any other process sufficient to break bonds (e.g., hydrogen bonds) in the strain inducing layer to prevent or limit defects while also imparting additional strain to a channel region of the second field effect transistor structure.

In developing this methodology 100, the inventors have appreciated that if the strain inducing layer were to remain in place over the first (e.g., p-type) field-effect transistor structure while the treatment is applied; it can lead to nickel agglomeration adjacent to the gate of the first (e.g., p-type) field-effect transistor structure—particularly when high strains are desired. Therefore, as shown in FIG. 1, the strain inducing layer is removed from over the first (e.g., p-type) field effect transistor structure prior to the treatment. This helps to limit nickel agglomeration and therefore helps facilitate higher levels of strain (e.g., greater than 1.57 Gpa) to correspondingly increase carrier mobility in the channel region of the second field effect transistor structure and improve device performance.

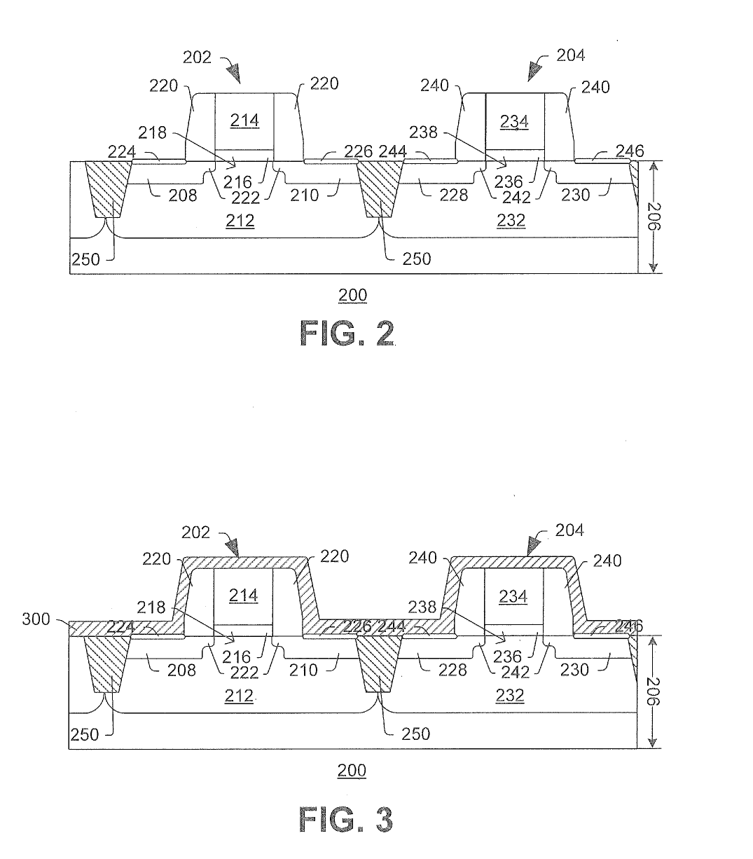

To show a specific example of how FIG. 1's manufacturing process can be implemented, FIGS. 2-7 show a series of cross sectional views at various stages of the manufacturing process. Although these cross-sectional views show one example of how the manufacturing process 100 could be carried out, FIGS. 2-7 do not limit the scope of the present disclosure in any way. Thus, while methods illustrated and described herein may be illustrated and/or described as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Further, one or more of the acts depicted herein may be carried out in one or more separate acts and/or phases, and are not limited to the structures illustrated in FIGS. 2-6.

FIG. 2 shows a cross-sectional view of a semiconductor device 200 at one stage of manufacture. The semiconductor device 200 includes a first (e.g., p-type) field effect transistor structure 202 and a second (e.g., n-type) field effect transistor structure 204, which are formed on a semiconductor substrate 206. It will be appreciated that “semiconductor substrate” as referred to herein may comprise any type of semiconductor material including a bulk silicon wafer, a binary compound substrate (e.g., GaAs wafer), a ternary compound substrate (e.g., AlGaAs), or higher order compound wafers, among others. Further, the semiconductor substrate 206 can also include non semiconductor materials such as oxide in silicon-on-insulator (SOI), partial SOI substrate, polysilicon, amorphous silicon, or organic materials, among others. In some embodiments, the semiconductor substrate 206 can also include multiple wafers or dies which are stacked or otherwise adhered together. The semiconductor substrate 206 can include wafers which are cut from a silicon ingot, and/or any other type of semiconductor/non-semiconductor and/or deposited or grown (e.g. epitaxial) layers formed on an underlying substrate.

The first (e.g., p-type) field effect transistor structure 202 includes source/drain regions (208, 210) which have a first conductivity type (e.g., p+). The source/drain regions (208, 210) are typically implanted near an upper surface of the semiconductor substrate 206 and are disposed in a well 212 having a second conductivity type (e.g., n-well). A conductive gate electrode 214, which is electrically isolated from the substrate by a gate dielectric layer 216, overlies a channel region 218 in the well 212. Single-layer or multi-layer sidewall spacers 220 are disposed about opposite sides of the gate electrode 214 and have source/drain extension regions 222 there under. Source/drain contact regions (224, 226), which can comprise a metal silicide (e.g., nickel silicide), are formed near the top surface of the substrate 206 in the source/drain regions (208, 210). These source/drain contact regions (224, 226) facilitate ohmic contact to the source/drain regions (208, 210) from higher level layers (e.g., a contact, via, and or interconnect layers).

During operation, a voltage which is greater than a pre-determined threshold voltage (V_{T}), is selectively applied to the gate electrode 214. If a voltage having a magnitude less than V_{T} is applied to the gate electrode 214, the channel region 218 represents a large resistance and little or no current flows between the source/drain regions (208, 210)—the first field effect transistor structure 202 is “off”. However, when a gate voltage having a magnitude greater than V_{T} is applied, V_{T} depletes carriers from the channel region 218, thereby causing majority carriers (e.g., holes) to enter the channel region 218 from the source/drain regions (208, 210). When a bias is applied across the source/drain regions, these majority carriers in the charged channel region drift (i.e., are swept) from one source/drain region to the other thereby causing significant current to flow—the first field effect transistor structure 202 is on. Thus, the first field effect transistor structure 202 can act somewhat like a switch in that it can vary between an on state and an off-state, depending on the bias applied to the transistor.

The second (e.g., n-type) field effect transistor structure 204 includes source/drain regions (228, 230) which have the second conductivity type (e.g., n+). The source/drain regions (228, 230) are typically implanted near the upper surface of the semiconductor substrate 206 and are disposed in a well 232 having the first conductivity type (e.g., p-well). A conductive gate electrode 234, which is electrically isolated from the substrate 206 by a gate dielectric layer 236, overlies a channel region 238 of the well 232. Sidewall spacers 240 are disposed about opposite sides of the gate electrode 234 and have source/drain extension regions 242 there under. Source/drain contact regions (244, 246), which can comprise a metal silicide (e.g., nickel silicide), are formed near the top surface of the substrate 206 in the source/drain regions (228, 230), and facilitate ohmic contact to the source/drain regions from higher level layers (e.g., a contact, via, and or interconnect layer). The second field effect transistor 204 can also act somewhat like a switch in that it can vary between an on state and an off-state, depending on the bias applied to the transistor, albeit the biases are reversed with respect to the first field effect transistor due to the opposite conductivity types associated with the first field effect transistor.

To keep the first and second field effect transistor structures 202, 204 electrically isolated from one another, isolation structures 250 are often buried in the substrate 206 between such field effect transistor structures. These isolation structures 250 are often made of a dense oxide, and can be referred to in some contexts as shallow trench isolation (STI) structures.

As shown in FIG. 3, a strain inducing layer 300 is then formed over the surface of the semiconductor device 200. The strain inducing layer 300 can be made up of silicon nitride, oxide, or silicon germanium, among others. Although this strain inducing layer 300 can impart tensile strain to the second (e.g., n-type) FET structure's channel region 238, other strain inducing layers (not illustrated) can be provided to provide compressive strain to the first (e.g., p-type) FET structure's channel region 218. In some embodiments, the strain inducing layer 300 acts as a contact etch stop layer (CESL).

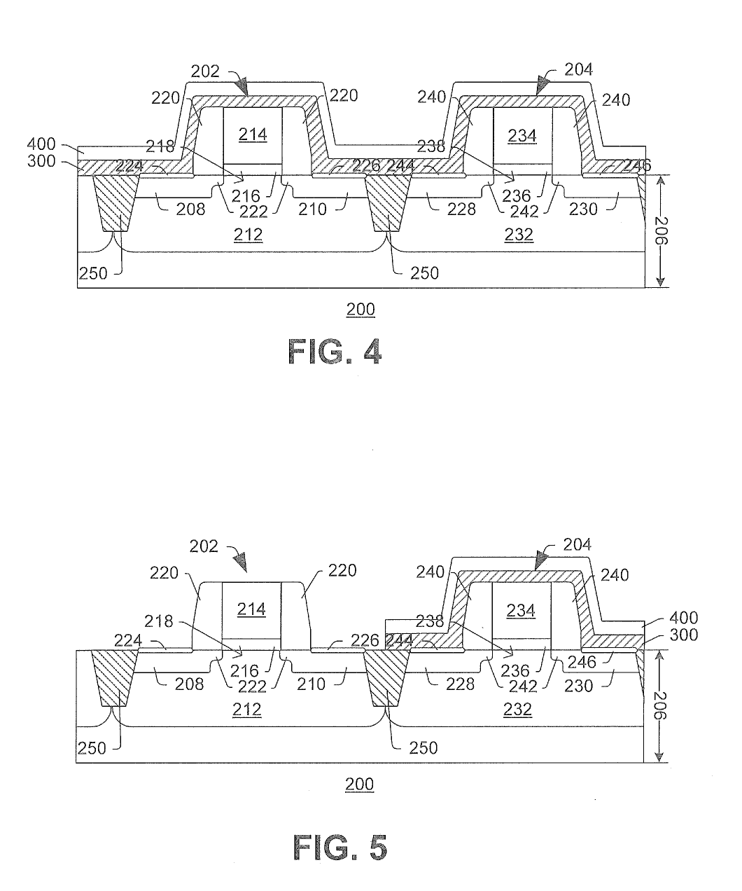

In FIG. 4, an etch stop layer 400 is formed over the strain-inducing layer 300. The etch stop layer 400 can enhance the efficiency of the strain-induced layer 300, particularly when the etch stop layer 400 is in contact with the underlying strain-inducing layer 300. In addition, the etch stop layer 400 is advantageous in that it provides excellent mechanical stability and is relatively impervious to moisture, which may be advantageous in later processing, such as in chemical-mechanical polishing (CMP), for example. In some embodiments, the etch stop layer 400 can comprise tetraethyl orthosilicate (TEOS).

In FIG. 5, the strain-inducing layer 300 and etch stop layer 400 are selectively removed over the first (e.g., p-type) field effect transistor structure 202, but are left in place over the second (e.g., n-type) field effect transistor structure 204. To provide this selective removal of these layers 300, 400; a mask (not shown) is often formed over the second field effect transistor structure 204. With the mask is in place, an etch (e.g., a dry etch, such as a plasma etch) is then used to remove the strain-inducing layer 300 and etch stop layer 400 from over the un-masked region 202.

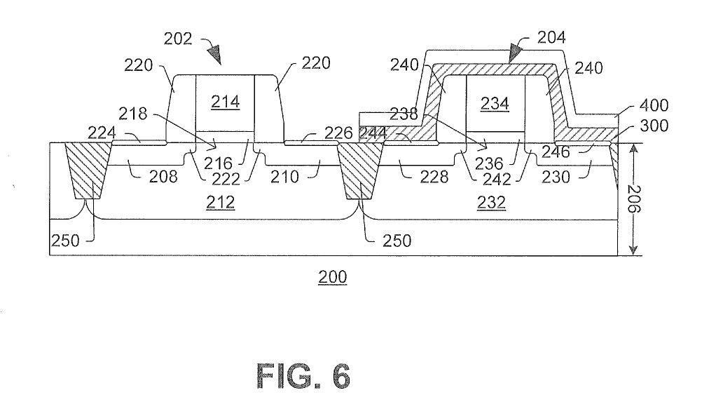

In FIG. 6, a treatment is performed on the remaining strain-inducing layer 300 and etch stop layer 400 to induce additional strain to the channel region 238 (e.g., beyond the strain induced by forming the strained-inducing layer 300 in FIG. 3). This treatment can break the Si—H and N—H bonds in the strain inducing layer 300 and form more Si—N bonds. These addition Si—N bonds produce greater levels of strain than without the treatment. In some embodiments, the treatment is realized by applying a predetermined electromagnetic spectrum (e.g., applying an ultra-violet (UV) cure) to the layers 300, 400; but in other embodiments other energy sources could be used to power this reaction. For example, a thermal process (e.g., anneal) and plasma, among others, could be used in other embodiments.

Although the formation of the strain-inducing layer 300 and etch stop layer 400 in and of themselves (e.g., in FIG. 3 and/or FIG. 4) can produce tensile strain in the channel regions of the field effect transistors, problems may occur in some instances if strain-inducing layer 300 and etch stop layer 400 extended over both field effect transistor structures 202, 204 when the treatment was applied. In particular, the additional strain induced by the treatment over the first (e.g., n-type) field effect transistor 202 can cause mouse bite defects adjacent to the gate electrode 214 and/or source/drains 224/226, for example. Notably, the mouse bite defects are formed primarily only over the first (e.g., p-type) field effect transistor structure 202 when the additional strain from the treatment is applied. Therefore, by removing the stain-inducing layer 300 and etch stop layer 400 from over the first (e.g., p-type) field effect transistor structure 202 prior to the treatment, the treatment allows the application of additional strain while limiting the formation of mouse bite defects.

It is noted that although the illustrated implementations have been discussed above in association with lateral MOSFET transistor devices, other implementations are also possible. For example, the use of a treatment as described above may also be used in vertical MOSFET devices, wherein the source/drain regions of a field effect transistor are oriented in a vertical manner over one another. The concepts disclosed herein may be advantageously employed in association with a wide variety of electrical devices, such as memory cells, bipolar transistors, or the like. Also, many of the elements illustrated and discussed are not required in all implementations. For example, although sidewall spacers, source/drain extension regions, and STI regions were illustrated and discussed, these features are omitted in some embodiments. Also, although the illustrated embodiments show single layer spacers, it will be appreciated that other multi-layer spacer structures are also contemplated as falling within the scope of the present disclosure.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description and the claims, such terms are intended to be inclusive in a manner similar to the term “comprising.”

What is claimed is:

1. A method comprising:
providing a strain inducing layer over an n-type field effect transistor structure on a semiconductor substrate, wherein the strain inducing layer does not extend over a p-type field effect transistor structure on the semiconductor substrate; and
performing a treatment of the strain inducing layer to induce strain into a channel region of the n-type field effect transistor structure.

2. The method of claim 1, wherein the n-type field effect transistor structure comprises:
a n-type source region formed in the semiconductor substrate;
a n-type drain region formed in the semiconductor substrate;
an p-type body region formed in the semiconductor substrate and separating the n-type source and drain regions; and
a gate electrode formed near the p-type body region but electrically isolated there from by a gate dielectric;
wherein the strain inducing layer overlies the gate electrode and wherein the channel region is arranged in the p-type body region under the gate dielectric.

3. The method of claim 1, wherein the stress inducing layer comprises a silicon nitride layer.

4. The method of claim 1, further comprising:
forming an etch stop layer over the strain inducing layer so the etch stop layer contacts the strain inducing layer.

5. The method of claim 4, wherein the etch stop layer comprises tetraethyl orthosilicate (TEOS).

6. The method of claim 1, wherein the treatment is energetically sufficient to break existing bonds in the strain-inducing layer and thereby induce formation of additional bonds to impart the tensile strain in the channel region of the n-type field effect structure.

7. The method of claim 1, wherein the treatment comprises at least one of the following: an ultra-violet cure, a thermal process, or a plasma process.

8. A method comprising:
forming a strain inducing layer over a p-type field effect transistor structure and an n-type field effect transistor structure;
selectively removing the strain inducing layer from over the p-type field effect transistor structure while leaving the strain inducing layer over the n-type field effect transistor structure; and
performing a treatment of the strain inducing layer over the n-type field effect transistor structure after the selective removal of the strain-inducing layer from over the p-type field effect transistor structure.

9. The method of claim 8, wherein the n-type field effect transistor structure comprises:
a n-type source region formed in a semiconductor substrate;
a n-type drain region formed in the semiconductor substrate;
an p-type body region formed in the semiconductor substrate and separating the n-type source and drain regions;
a gate electrode formed near the p-type body region but electrically isolated there from, wherein the strain inducing layer overlies the gate electrode; and
a gate dielectric sandwiched between the gate electrode and a channel region in the p-type body region, thereby providing electrical isolation between the gate electric and p-type body region;
wherein the treatment interacts with the strain-inducing layer to impart tensile strain in the channel region of the n-type field effect transistor structure.

10. The method of claim 9, further comprising:
forming a nickel silicide contact to ohmically couple the n-type source region to an interconnect layer over the strain inducing layer.

11. The method of claim 8, wherein the strain inducing layer comprises a contact etch stop layer that produces a tensile strain in a channel region of the n-type field effect transistor.

12. The method of claim 11, further comprising:
forming an etch stop layer over the contact etch stop layer so the etch stop layer contacts the contact etch stop layer.

13. The method of claim 12, further comprising:
forming a mask over the etch stop layer and strain-inducing layer over the n-type field effect transistor, wherein the mask does not extend over the etch stop layer and strain-inducing layer over the p-type field effect transistor; and
performing an etch to remove the etch stop layer and strain inducing layer over the p-type field effect transistor.

14. The method of claim 13, wherein the treatment is performed after the etch but while the etch stop layer and strain inducing layer are in place over the n-type field effect transistor.

15. The method of claim 8, wherein the stress inducing layer comprises a silicon nitride layer.

16. The method of claim 15, wherein the treatment is are energetically sufficient to break Si—H and N—H bonds to induce formation of additional Si—N bonds to impart the tensile strain in the channel region of the n-type field effect structure.

17. The method of claim 8, further comprising:
forming a shallow-trench isolation structure between the p-type field effect transistor structure and the n-type field effect transistor structure to electrically isolate the field effect transistor structures from one another.

18. A method comprising:
forming a strain inducing layer over a first field effect transistor structure having source/drain regions of a first conductivity type and over a second field effect transistor structure having source/drain regions of a second conductivity type opposite the first conductivity type;
selectively removing the strain inducing layer from over the first field effect transistor structure while leaving the strain inducing layer over the second field effect transistor structure; and
performing a treatment of the strain inducing layer remaining over the second field effect transistor structure after the selective removal of the strain-inducing layer from over the first field effect transistor structure.

19. The method of claim 18, wherein the first field effect transistor structure corresponds to an n-type MOSFET and wherein the second field effect transistor structure corresponds to a p-type MOSFET.

20. The method of claim 19, further comprising:
forming a tetraethyl orthosilicate (TEOS) layer over the strain inducing layer so the TEOS layer contacts strain inducing layer.

21. The method of claim 20, further comprising:
forming a mask over the TEOS layer over the n-type MOSFET, wherein the mask does not extend over the p-type MOSFET; and
performing an etch to remove the TEOS layer and strain inducing layer over the p-type MOSFET.

22. The method of claim 21, wherein the treatment is performed after the etch has removed the TEOS layer and strain inducing layer over the p-type MOSFET, and is performed while the TEOS layer and strain inducing layer remain over the n-type MOSFET.

23. The method of claim 18, wherein the stress inducing layer comprises a silicon nitride layer.

24. The method of claim 23, wherein the treatment is energetically sufficient to break Si—H and N—H bonds to induce formation of additional Si—N bonds to impart the tensile strain in a channel region of the second field effect transistor structure.

25. The method of claim 24, wherein the tensile strain induced in the channel region of the second field effect transistor structure is greater than 1.57 Gpa after the treatment.
